(19) United States
(12) Patent Application Publication
(10) Pub. No.: US 2019/0280051 A1
(43) Pub. Date: Sep. 12, 2019

(54) ELECTROLUMINESCENT DISPLAY INTEGRATED WITH TOUCH SENSOR AND METHOD OF FORMING THE SAME

(71) Applicant: INT TECH CO., LTD., Hsinchu County (TW)

(72) Inventor: SHIH-SONG CHENG, KAOHSIUNG CITY (TW)

(21) Appl. No.: 15/916,627

(22) Filed: Mar. 9, 2018

(51) Int. Cl. H01L 27/32; H01L 51/00; H01L 51/52; G06F 3/044; G06F 3/041

(52) U.S. Cl. CPC H01L 27/323; H01L 27/3211; H01L 27/3248; H01L 51/0005; G06F 2203/04103; H01L 51/5221; G06F 3/044; G06F 3/0412; H01L 51/5206

(57) ABSTRACT

An electronic device includes a substrate, a display unit and a touch sensor unit. The substrate includes a first region and a second region, wherein the first region and the second region are separate from each other. The display unit, disposed at the first region of the substrate, includes an electroluminescent (EL) device that includes a first cathode electrode in a patterned cathode layer over an interconnection structure disposed between the substrate and the EL device. The touch sensor unit, disposed at the second region of the substrate, is configured to detect a touch event. The touch sensor unit includes a second cathode electrode in the patterned electrode layer, and a capacitor defined in the interconnection structure. The capacitor includes a conductive plate electrically coupled to the second cathode electrode.

### BACKGROUND

Electroluminescent (EL) display panels have gradually become one of the development trends in the flat-panel display field due to the advantages of auto-luminescence, high resolution, high brightness, low thickness, light weight, wide viewing angle, rapid response, low energy consumption and the like. Nowadays, touch devices are widely used in conjunction with EL display panels. With touch devices, a user can easily operate on an electronic device such as a smart phone or a laptop computer. While touch devices bring a new era of user interface, touch sensitivity has been the subject of interest in developing advanced touch devices.

### SUMMARY

Embodiments of the present invention provide an electronic device. The electronic device includes a substrate, a display unit and a touch sensor unit. The substrate includes a first region and a second region, wherein the first region and the second region are separate from each other. The display unit, disposed at the first region of the substrate, includes an electroluminescent (EL) device that includes a first cathode electrode in a patterned cathode layer over an interconnection structure disposed between the substrate and the EL device. The touch sensor unit, disposed at the second region of the substrate, is configured to detect a touch event. The touch sensor unit includes a second cathode electrode in the patterned electrode layer, and a capacitor defined in the interconnection structure. The capacitor includes a conductive plate electrically coupled to the second cathode electrode.

In an embodiment, the EL device includes a first anode electrode in a patterned anode layer on the interconnection layer, and a light-emitting layer between the first cathode electrode and the first anode electrode.

In another embodiment, the touch sensor unit includes a second anode electrode in the patterned anode layer. The second anode electrode physically contacts the second cathode electrode.

In yet another embodiment, the interconnection structure includes a first conductive layer over the substrate, and a second conductive layer over the first conductive layer. The capacitor is defined between the first conductive layer and the second conductive layer.

In still another embodiment, the interconnection structure further includes a third conductive layer over the second conductive layer, and a conductive via connecting the second conductive layer and the third conductive layer.

In yet still another embodiment, the third conductive layer is coupled to the second anode electrode.

In still yet another embodiment, the display unit is juxtaposed with the touch sensor unit.

In a further embodiment, the display unit includes a transistor on the substrate for switching the EL device.

In another further embodiment, the touch sensor unit includes transistors on the substrate for detecting the touch event.

Embodiments of the present invention provide a method of forming a display unit integrated with a touch sensor unit. The method includes providing a substrate including a first region for a display unit and a second region for a touch sensor unit, forming on the substrate an interconnection structure for electrical connection, forming at the second region a capacitor defined in the interconnection structure, the capacitor configured to detect a touch event, forming a patterned anode layer on the interconnection structure, and forming a patterned cathode layer over the patterned anode layer, wherein at the second region the patterned cathode layer is disposed on the patterned anode layer.

In an embodiment, after forming the patterned anode layer, the method further includes forming a pixel defining layer (PDL) on the patterned anode layer. The PDL defines luminous regions separate from each other.

In another embodiment, the method further includes filling a light-emitting material in the luminous regions except those over the second region.

In still another embodiment, forming the patterned cathode layer further includes forming the patterned cathode layer on the PDL. The patterned cathode layer fills the luminous regions at the second region.

In yet another embodiment, after providing the substrate, the method further includes forming on the substrate at the first region a first transistor for switching an electroluminescent (EL) device.

In still yet another embodiment, after providing the substrate, the method further includes forming on the substrate at the second region second transistors for detecting a touch event.

In yet still another embodiment, forming the capacitor further includes forming a first conductive layer in the interconnection structure, and forming a second conductive layer over the first conductive layer. The capacitor is defined between the first conductive layer and the second conductive layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an electronic device, in accordance with some embodiments.

FIG. 2 is a circuit diagram of an exemplary circuit of a touch sensor unit in the electronic device illustrated in FIG. 1.

FIG. 3 is a schematic diagram of a display and sensor module in the electronic device illustrated in FIG. 1, in accordance with some embodiments.

FIG. 4 is a flow diagram showing a method of forming a display unit integrated with a touch sensor unit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

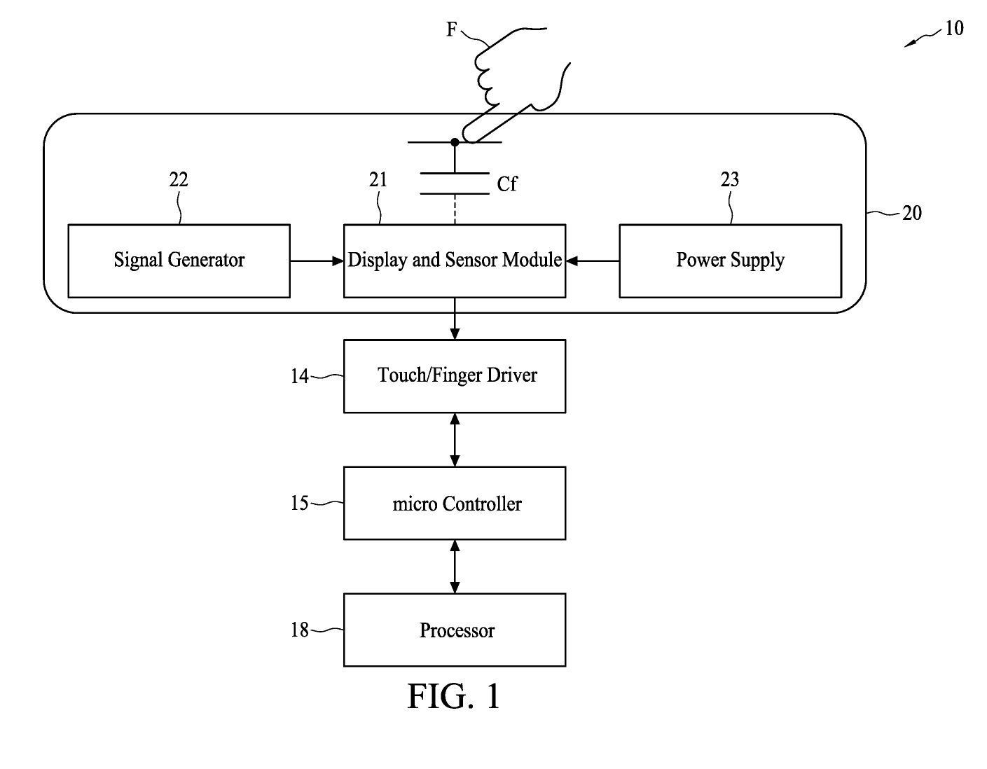

FIG. 1 is a block diagram of an electronic device 10, in accordance with some embodiment. Examples of the electronic device 10 include computing devices such as cell phones, smartphones, netbooks, laptops, tablets and iPods.

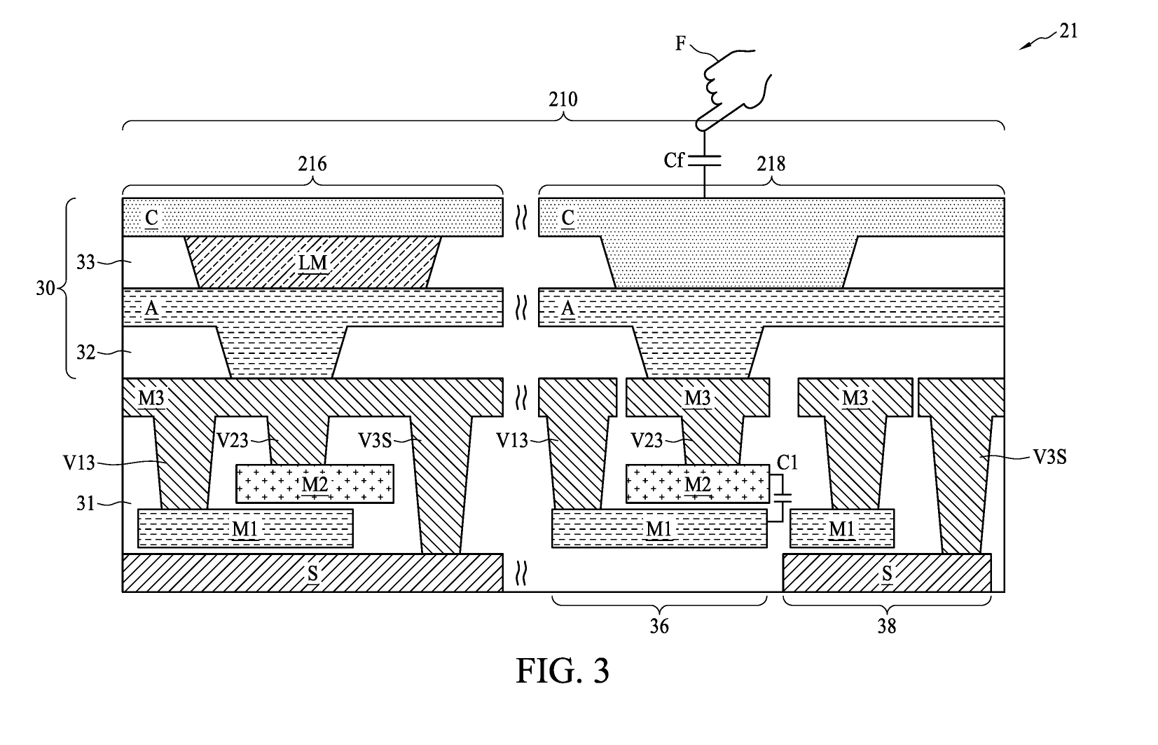

Referring to FIG. 1, the electronic device 10 includes a sensing module 20, a driver 14, a micro controller 15, a display 16 and a processor 18. The sensing module 20 is configured to, under control of the micro controller 15 via the driver 14, detect the presence of an object F, for example, a fingerprint of a user or a stylus. Information on the object, such as ridge or valley data related to the fingerprint, is sent to the processor 18 for further processing. The sensing module 20 includes a display and sensor module 21, powered by a power supply 23, for detecting the object in response to control signals SENSE, S1 and S2 provided by a signal generator 22. The display and sensor module 21 includes at least one display unit integrated with a touch sensor unit, which will be described in detail with reference to FIG. 3.

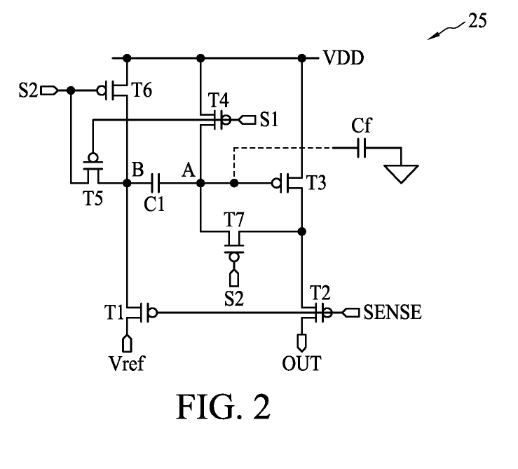

FIG. 2 is a circuit diagram of an exemplary circuit 25 of a touch sensor unit in the electronic device 10 illustrated in FIG. 1.

Referring to FIG. 2, the circuit 25 is configured in a 7T1C structure that includes seven transistors T1 to T7 and a capacitor C1. The circuit 25 is intended for purposes for illustration only and not intended to limit the scope of the present disclosure. Specifically, a touch sensor unit in the display and sensor module 21 is not limited to the 7T1C structure or any specific structures. A touch sensor unit that includes other number of transistors may also fall within the contemplated scope of the present disclosure. In the present embodiment, each of the transistors T1 to T7 includes a p-type thin film transistor (TFT) or a p-type metal-oxide-semiconductor (PMOS) transistor. Detailed discussion on circuit operation is disclosed in U.S. patent application, entitled “CIRCUIT FOR FINGERPRINT SENSING AND ELECTRONIC DEVICE COMPRISING THE CIRCUIT,” and filed on the same date as the subject application by the same applicant, the disclosure of which is hereby incorporated herein by reference.

FIG. 3 is a schematic diagram of the display and sensor module 21 in the electronic device 10 illustrated in FIG. 1, in accordance with some embodiments.

Referring to FIG. 3, the display and sensor module 21 includes a display unit 216 and a touch sensor unit 218. The display unit 216 and the touch sensor unit 218 are integrated with each other in a pixel area 210 of the electronic device. In addition, the touch sensor unit 218 may be formed in a manufacturing process for forming the display unit 216. Moreover, an array of display units 216 and touch sensor units 218 may be arranged in the pixel area 210. For brevity, only one display unit 216 and one touch sensor unit 218 are illustrated. In an embodiment, a display unit 216 in the array corresponds to a sub-pixel in the pixel area 210. A sub-pixel is configured to display a certain color such as one of color red (R), color green (G) or color blue (B). In an embodiment, for high-resolution applications, a touch sensor unit 218 serves a single display unit 216, which together form a display and sensor module 21. In that case, the display unit 216 and the touch sensor unit 218 are juxtaposed with each other in the pixel area 210. In other embodiments, a touch sensor unit 218 serves multiple display units 216.

The display unit 216 includes a substrate S, an interconnection structure comprising conductive layers M1, M2, M3 and conductive vias V13, V23, V3S in a first dielectric layer 31 on the substrate S, and an electroluminescence (EL) device 30 on the interconnection structure. The substrate S supports the electroluminescence (EL) device 30. In an embodiment, the substrate S includes a semiconductor material, such as silicon. Alternatively, the substrate S may include other semiconductor materials, such as silicon germanium, silicon carbide, gallium arsenide, or the like. The substrate S may be a p-type semiconductive substrate (acceptor type) or an n-type semiconductive substrate (donor type). Moreover, a transistor such as a TFT (not shown), which serves as a switch element for the EL device 30, is formed on the substrate S.

The first dielectric layer 31 is used for electrically insulating the conductive features M1, M2 and M3. The first dielectric layer 31 is made of dielectric material including, for example, oxide or nitride.

The conductive layers M1, M2 and M3 are arranged as laterally extending conductive lines which, where necessary, are electrically connected by the vertically extending conductive vias V13, V23 and V3S. Moreover, the conductive layers M1, M2 and M3 may be coupled with electrodes of the TFT to create an electrical connection between the TFT and the EL device 30. The conductive layers M1, M2, M3 and the conductive vias V13, V23, V3S are made of conductive material suitable for interconnection, for example, copper, silver, aluminum, tungsten, a combination thereof, of the like. In the present embodiment, exemplary conductive layers M1, M2, M3 and exemplary conductive vias V13, V23 and V3S are shown for illustrated purposes only. Variations and modifications for the interconnection structure are within the contemplated scope of the present disclosure, such as more layers of conductive lines interconnected through conductive vias and more layers of dielectric layers formed therebetween.

The EL device 30 includes an anode electrode labeled A, a cathode electrode labeled C, and a light-emitting layer LM between the anode A and the cathode C. The EL device 30 includes, for example, a current-driven element that may include an organic light emitting diode (OLED), a micro LED or a quantum dot LED (QLED). The light-emitting layer LM is disposed at a luminous region of the display unit 216 which serves as a sub-pixel in the pixel area 210. The light-emitting layer LM is a film of organic compound that emits light in response to an electric current. A TFT corresponding to the sub-pixel is configured to control the emission of the light-emitting layer LM. A second dielectric layer 32, formed on the interconnection structure, is used for back planarization. Suitable materials for the second dielectric layer 32 may include organic dielectric and photoresist.

The anode A serves as an emitter of the EL device 30. When an electrical current flows through the light-emitting layer LM or a potential difference occurs, the anode A loses electrons (or “receives holes”). In contrast, the cathode C serves as a collector of the EL device 30. The cathode C injects electrons when an electrical current flows through the light-emitting layer LM.

The light-emitting layers LM at the luminous regions of R. G and B colors are configured to inject liquid organic light-emitting materials capable of emitting light of R, G and B colors after application of voltages into the luminous regions defined by a third dielectric layer 33 by means of inkjet printing. The third dielectric layer 33 serves as a pixel defining layer (PDL), which is configured to define sub-pixels, expose the luminous regions of the sub-pixels, and cover remaining areas. An organic dielectric layer or a photoresist layer may be used as the PDL.

An exemplary method of forming the display unit 216 is briefly discussed below, taking the EL device 30 as an OLED device as an example. The OLED device may comprise a red (R) sub-pixel, a green (G) sub-pixel and a blue (B) sub-pixel, in which each sub-pixel unit is provided with at least one TFT. Moreover, the OLED device generally includes at least three layers: a cathode layer, an anode layer, and a light-emitting layer between the cathode layer and the anode layer. The area of the cathode layer, the light-emitting layer and the anode layer may correspond to the luminous regions. The method for manufacturing a TFT and an OLED in a sub-pixel mainly comprises the following operations.

Functional layers of the TFT, including a gate electrode, a gate insulating layer, an active layer and source/drain electrodes are formed on a substrate. The substrate includes a first region for the display unit 216, and a second region 218, separate from the first region, for the touch sensor unit 218.

Next, an interconnection structure, which includes conductive layers and conductive vias in a dielectric layer, is formed on the substrate. A first pixel electrode (anode) layer is formed to connect with the drain electrode. A PDL is formed on the first pixel electrode. The PDL covers the TFT and expose regions for manufacturing the OLED. The PDL is also configured to separate luminous regions, in which OLEDs are disposed, of different sub-pixel from each other. A light-emitting layer of the OLED is then formed by inkjet printing a liquid organic light-emitting material. Subsequently, a second pixel electrode (cathode) layer is formed on the PDL and the OLED.

The touch sensor unit 218 includes a capacitor region 36 in which a capacitor C1 is defined, and a transistor region 38 in which transistors are provided for sensing a touch event Cf of an object F such as a finger or a stylus. An example of a circuit including a capacitor C1 and transistors can be found in the above-mentioned application filed by the same applicant. The capacitor C1 is defined by a first conductive layer M1 and a second conductive layer M2 in the capacitor region 36, and works in conjunction with the transistors in order to sense a touch event. The transistors, for example, transistors T1 to T7 as illustrated in FIG. 2, are disposed on the substrate S in the transistor region 38.

The touch sensor unit 218 may be manufactured as the display unit 216 is manufactured in a same manufacturing process. For example, while a switching TFT of the display unit 216 is being formed on the substrate S, the transistors for sensing a touch event Cf are formed on the substrate S. In addition, the capacitor C1 can be defined while the interconnection structure including the first conductive layer M1 and the second conductive layer M2 is formed. Moreover, the light-emitting layers LM defined by the PDL in the display unit 216 are replaced by a cathode material in the touch sensor unit 218. As a result, while the light-emitting layers LM are formed at regions defined by PDL by inkjet printing in the first region for the display unit 216, no organic light-emitting material is inkjet-printed at regions defined by PDL in the second region for the touch sensor unit 218. Instead, while a cathode layer is formed on the PDL and the light-emitting layers LM at the first region by, for example, a deposition process, a cathode layer is also formed at the second region by the deposition process, filling the regions defined by the PDL.

Since the display unit 216 and the touch sensor unit 218 are formed on a same substrate in a manufacturing process, the touch sensor unit 218 is juxtaposed with the display unit 216 or disposed at a lateral side of the display unit 216. As a result, the entire height of the electronic device 10 can be reduced, as compared to some existing structures in which a display unit is stacked on a touch sensor unit. With the reduced height, the electronic device 10 can be designed in a compact profile. In addition, the second conductive layer M2 as a conductive plate in the capacitor C1 is electrically coupled via the conductive via V23 to the third conductive layer M3, which in turn coupled to the anode layer at the second region, which in turn coupled to the cathode layer at the second region. The cathode layer, anode layer, third conductive layer M3 and the second conductive layer M2 are in electrical connection with one another at the second region, and together can be deemed a conductive plate of the capacitor C1. As a result, during a touch event, the cathode layer disposed atop is proximal to the object F and can more precisely detect the touch event Cf, as compared to some existing in-cell or on-cell structures. With the cathode layer at the second region serving as a plate of the capacitor C1 for detecting a touch event, the sensitivity of the touch sensor unit 128 is enhanced.

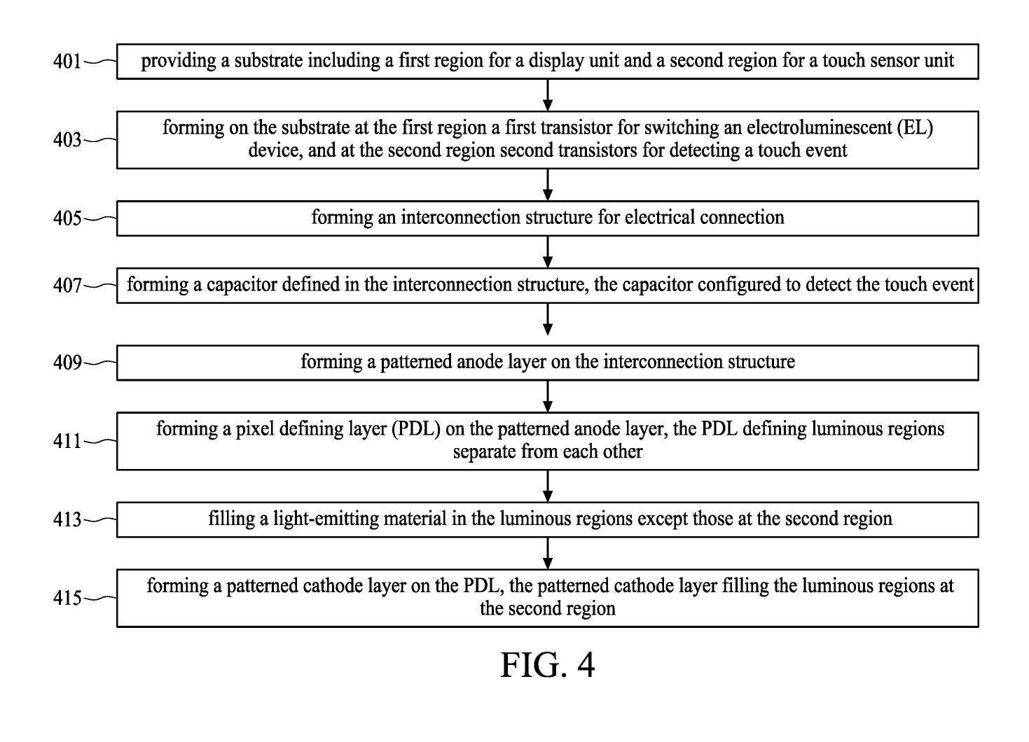

FIG. 4 is a flow diagram showing a method of forming a display unit integrated with a touch sensor unit, in accordance with some embodiments.

Referring to FIG. 4, in operation 401 a substrate is provided. The substrate includes a first region for a display unit and a second region for a touch sensor unit.

In operation 403, a first transistor for switching an electroluminescent (EL) device is formed at the first region on the substrate. Moreover, second transistors for detecting a touch event are formed at the second region on the substrate.

In operation 405, an interconnection structure for electrical connection is formed.

In operation 407, a capacitor defined in the interconnection structure is formed. The capacitor is configured to work in conjunction with the second transistors in order to detect a touch event.

In operation 409, a patterned anode layer on the interconnection structure is formed. The patterned anode layer includes first anode electrodes at the first region and second anode electrodes at the second region. The first anode electrodes and the second anode electrodes are electrically independent of each other. Subsequently, a pixel defining layer (PDL) is formed on the anode layer in operation 411. The PDL defines luminous regions separate from each other.

Next, in operation 413 a light-emitting material is filled into in the luminous regions except those at the second region.

Then in operation 415 a patterned cathode layer is formed on the PDL. The patterned cathode layer fills the luminous regions at the second region. The patterned cathode layer includes first cathode electrodes at the first region and second cathode electrodes at the second region. The second cathode electrodes physically contact the second anode electrodes. The first cathode electrodes and the second cathode electrodes are electrically independent of each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a substrate including a first region and a second region, the first region and the second region being separate from each other;
a display unit, at the first region of the substrate, including an electroluminescent (EL) device that includes a first cathode electrode in a patterned cathode layer over an interconnection structure disposed between the substrate and the EL device; and
a touch sensor unit, at the second region of the substrate, configured to detect a touch event, the touch sensor unit including a second cathode electrode in the patterned electrode layer, and a capacitor defined in the interconnection structure, the capacitor including a conductive plate electrically coupled to the second cathode electrode.

2. The electronic device according to claim 1, wherein the EL device includes a first anode electrode in a patterned anode layer on the interconnection layer, and a light-emitting layer between the first cathode electrode and the first anode electrode.

3. The electronic device according to claim 2, wherein the touch sensor unit includes a second anode electrode in the patterned anode layer, the second anode electrode physically contacting the second cathode electrode.

4. The electronic device according to claim 3, wherein the interconnection structure includes a first conductive layer over the substrate, and a second conductive layer over the first conductive layer, and wherein the capacitor is defined between the first conductive layer and the second conductive layer.

5. The electronic device according to claim 4, wherein the interconnection structure further includes a third conductive layer over the second conductive layer, and a conductive via connecting the second conductive layer and the third conductive layer.

6. The electronic device according to claim 5, wherein the third conductive layer is coupled to the second anode electrode.

7. The electronic device according to claim 1, wherein the display unit is juxtaposed with the touch sensor unit.

8. The electronic device according to claim 1, wherein the display unit includes a transistor on the substrate for switching the EL device.

9. The electronic device according to claim 1, wherein the touch sensor unit includes transistors on the substrate for detecting the touch event.

10. A method, comprising:
providing a substrate including a first region for a display unit and a second region for a touch sensor unit;
forming on the substrate an interconnection structure for electrical connection;
forming at the second region a capacitor defined in the interconnection structure, the capacitor configured to detect a touch event;
forming a patterned anode layer on the interconnection structure; and
forming a patterned cathode layer over the patterned anode layer, wherein at the second region the patterned cathode layer is disposed on the patterned anode layer.

11. The method according to claim 10, after forming the patterned anode layer, further comprising:
forming a pixel defining layer (PDL) on the patterned anode layer, the PDL defining luminous regions separate from each other.

12. The method according to claim 11 further comprising:
filling a light-emitting material in the luminous regions except those over the second region.

13. The method according to claim 11, wherein forming the patterned cathode layer further comprises:
forming the patterned cathode layer on the PDL, the patterned cathode layer filling the luminous regions at the second region.

14. The method according to claim 10, after providing the substrate, further comprising:
forming on the substrate at the first region a first transistor for switching an electroluminescent (EL) device.

15. The method according to claim 10, after providing the substrate, further comprising:
forming on the substrate at the second region second transistors for detecting a touch event.

16. The method according to claim 10, wherein forming the capacitor further comprises:
forming a first conductive layer in the interconnection structure; and
forming a second conductive layer over the first conductive layer, wherein the capacitor is defined between the first conductive layer and the second conductive layer.
